(19) United States
(12) Patent Application Publication
(10) Pub. No.: US 2004/0252466 A1
(43) Pub. Date: Dec. 16, 2004

(54) Electrical card

(76) Inventor: Jang Bor-Ren, Taipei Hsien (TW)

Correspondence Address: TROXELL LAW OFFICE PLLC, SUITE 1404, 5205 LEESBURG PIKE, FALLS CHURCH, VA, 22041, US

(21) Appl. No.: 10/458,217

(22) Filed: Jun. 11, 2003

(51) Int. Cl. H05K 1/14

(52) U.S. Cl. 361/737

(57) ABSTRACT

An electrical card has a dielectric housing, a connector, a printed circuit board (PCB) mounted on the dielectric housing, a first shell, a second shell, a first cover and a second cover. The first cover and the second cover respectively form engaging edges at opposite sides thereof. The engaging edges are slantwise assembled into latching slots of the dielectric housing and facilitate positioning of the first cover and the second cover. When pressing the engaging edges, the first cover and the second cover are released from the dielectric housing thereby simplifying repairing. Engaging means is provided to connect the first shell, the second shell, the first cover, the second cover and the dielectric housing together thereby simplifying assembly and disassembly.

### BACKGROUND OF THE INVENTION

1. Field of the Invention

The present invention relates to an electrical card, and particularly to an electrical card adaptable for all types of wireless transmission devices, which is reliably assembled and easily disassembled for repairing.

2. Related Art

Wireless transmission facilitates information exchange, accordingly, electrical cards tend to be combined within wireless transmission devices. A conventional electrical card within a wireless transmission device comprises a dielectric housing, a printed circuit board (PCB) mounted on the dielectric housing, a connector electrically connecting with the PCB for signal Input/Output, a first shell and a second shell shielding the PCB, and a first cover and a second cover assembled together to be mounted onto a side of the dielectric housing. The conventional electrical card has following defects:

(1) uneasily repairing. The first shell and the second shell of the conventional electrical card are undetachable after assembly. Once the PCB or electrical components received in the first shell and the second shell cannot work, it is inevitable to violate the first shell and the second shell or to discard the electrical card, resulting in unreasonable cost;

(2) inefficient material management and manufacture flow. One of the first cover and the second cover is integrally formed with the dielectric housing such that the first cover and the second cover are required of the same type. As for manufacturers, different product lines are required for different types of covers, complicating manufacture flow and relevant material management; and

(3) unreliable assembly. The first shell and the second shell of the conventional electrical card are engaged to each other in different ways, such as hot application, integrated-shape, latching etc. Whereas, metal material and plastic material are unreliably assembled by hot application; integrated-shape cost too much; and the first shell and the second shell are inconveniently assembled by means of latching.

### SUMMARY OF THE INVENTION

Accordingly, an object of the present invention is to provide an electrical card which is reliably assembled and easily detached are has a first shell and a second shell detachable from a dielectric housing thereof for detecting and repairing.

Another object of the present invention is to provide an electrical card adaptable for all types of wireless transmission devices. A first cover and a second cover thereof are separately formed, and easily assembled or detached from the dielectric housing, thereby facilitating assembly.

The electrical card comprises engaging means distributed in the first shell, the second shell, the first cover, the second cover and the dielectric housing for assembling the first shell, the second shell, the first cover, the second cover and the dielectric housing together.

Either of the first shell and the second shell forms engaging edges at opposite sides thereof.

Protruding plates are respectively formed on bottoms of the first bar and the second bar. Latching slots are defined in the protruding plates, and the engaging edges slantwise extend into the latching slots in assembly. The engaging edges are removable from the latching slots by repairing tools, whereby the first shell and the second shell are easily disassembled. Biasing portions are respectively formed on ends of the first bar and the second bar, each including a guiding block for guiding an assembling arm of the first shell, and a locking block for latching an assembling hole of the assembling arms.

### BRIEF DESCRIPTION OF THE DRAWINGS

FIGS. 1-4 show an electrical card of the present invention, wherein the electrical card is disassembled from different aspects;

FIGS. 5A and 5B are front view and back view of the electrical card of FIG. 1;

FIG. 6 is an assembled view of the electrical card of FIG. 5b;

FIG. 7 is a cross-sectional view taken along the line 7-7 of FIG. 5A;

FIG. 8 is a partially enlarged view of FIG. 7;

FIG. 9 is similar to FIG. 7, wherein a first shell of the electrical card is removed;

FIG. 10 is a partially enlarged view of FIG. 9;

FIG. 11 is a plane view of a dielectric housing of the electrical card;

FIG. 12 is a partially enlarged view of FIG. 11;

FIG. 13 is an exploded view of the dielectric housing and a second shell of the electrical card;

FIG. 14 is an assembled view of FIG. 13; and

FIG. 15 is a partially enlarged and cross-sectional view taken along line 15-15 of FIG. 14.

### DESCRIPTION OF THE PREFERRED EMBODIMENTS

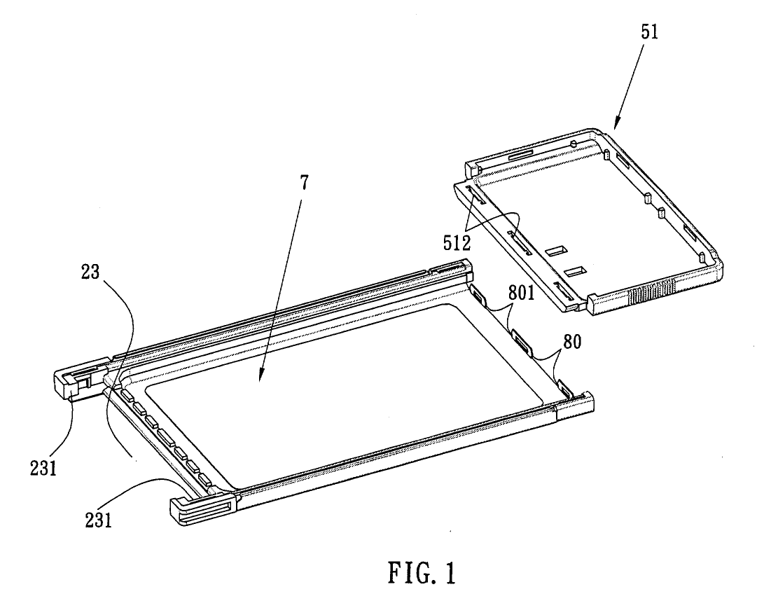

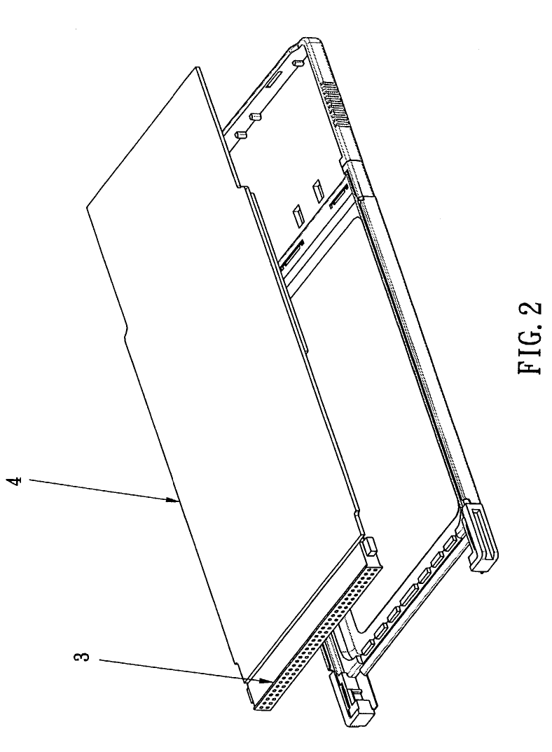

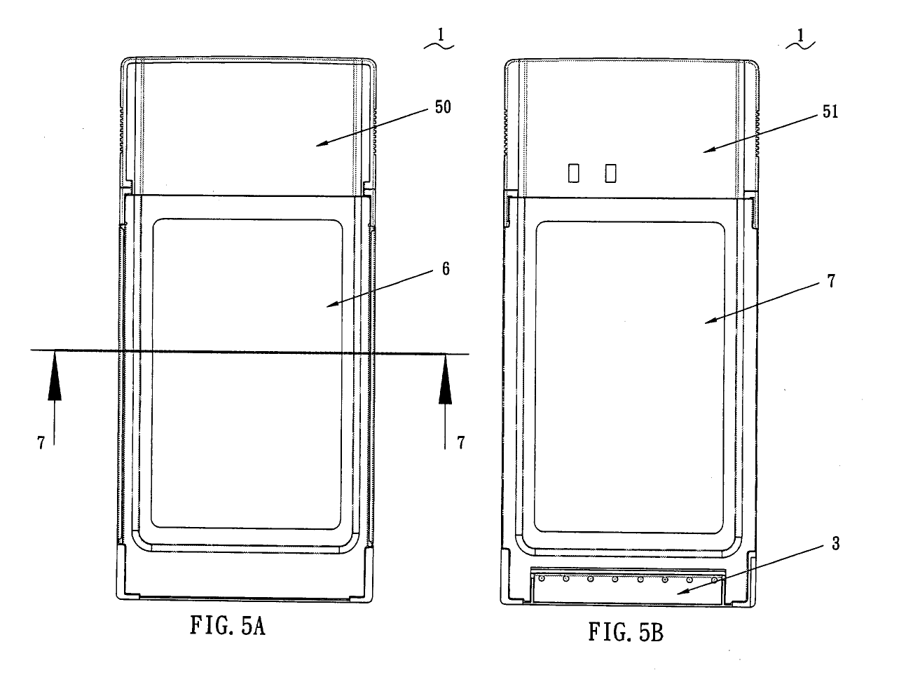

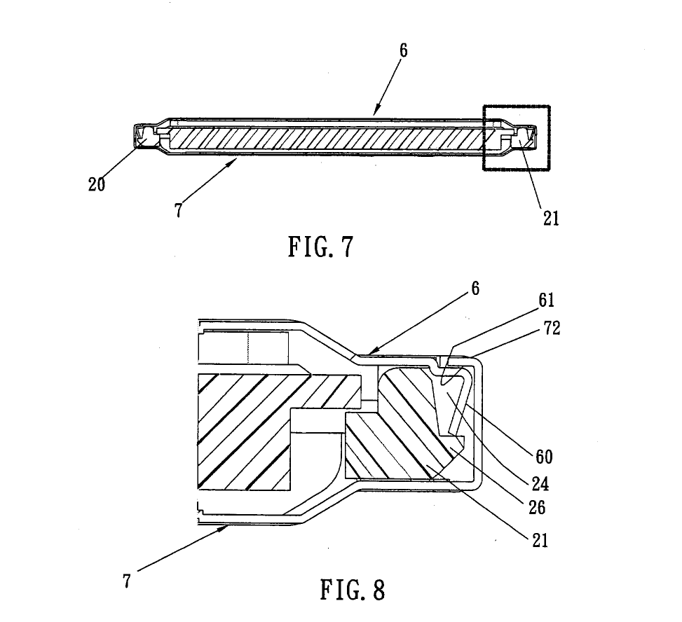

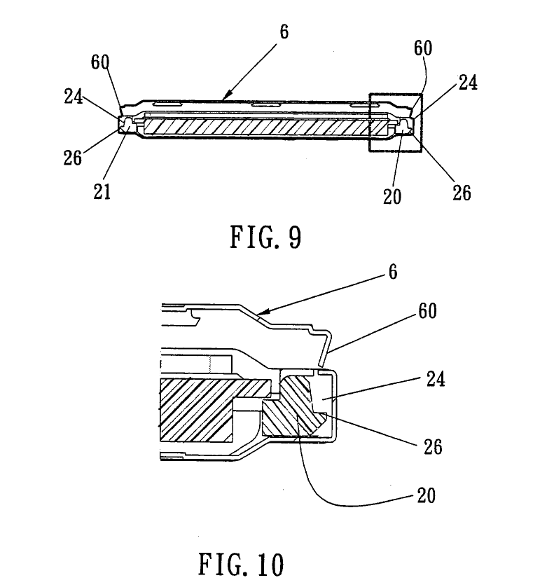

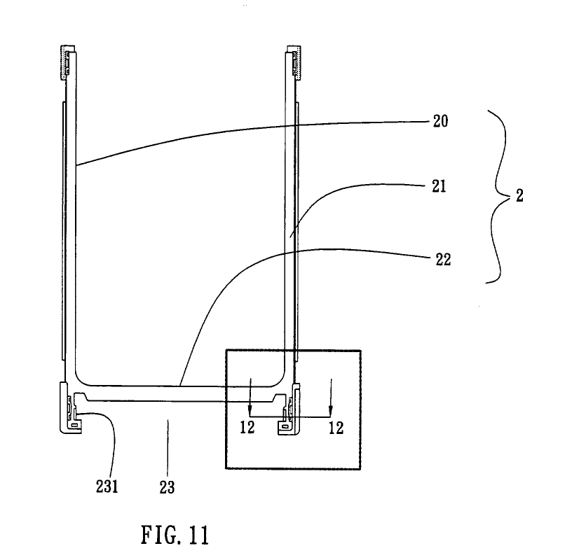

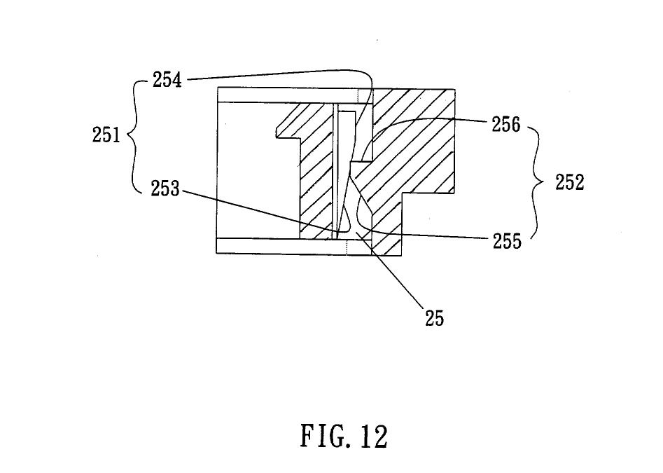

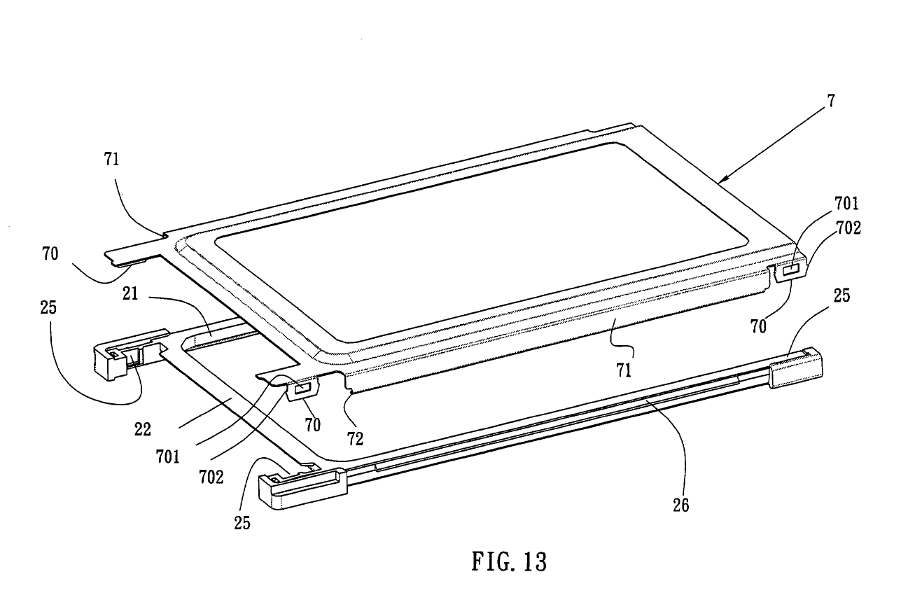

With reference to FIGS. 1 through 6, the electrical card 1 comprises a dielectric housing 2, a connector 3, a printed circuit board (PCB) 4, a first cover 50, a second cover 51, a first shell 6 and a second shell 7. Also referring to FIG. 11, the dielectric housing 2 includes a first bar 20, a second bar 21, and a transverse bar 22 connecting ends of the first bar 20 and the second bar 21. The first bar 20, the second bar 21 and the transverse bar 22 define an opening 23 for receiving the connector 3 therein. Tabs 231 project inwardly from respective ends of the first bar 20 and the second bar 21 and are opposing to each other for positioning the connector 3. As shown in FIGS. 9 and 10, protruding plates 26 are respectively formed on bottoms of and spaced apart from the first bar 20 and the second bar 21 and are opposite to each other. Latching slots 24 are defined in the protruding plates 26 for receiving engaging edges 60 of the first shell 6 (shown in FIGS. 7 and 8). Referring to FIGS. 12 and 13, biasing portions 25 are respectively formed on the ends of the first bar 20 and the second bar 21 and are opposite to each other. Each biasing portion 25 includes a guiding block 251 and a locking block 252. The guiding block 251 has an inclined surface 253 inwardly inclined from an end of the biasing portion 25, and a biasing surface 254 extending from an end of the inclined surface 253. The locking block 252 forms a sloped surface 255 and a locking surface 256 for guiding and locking the second shell 7.

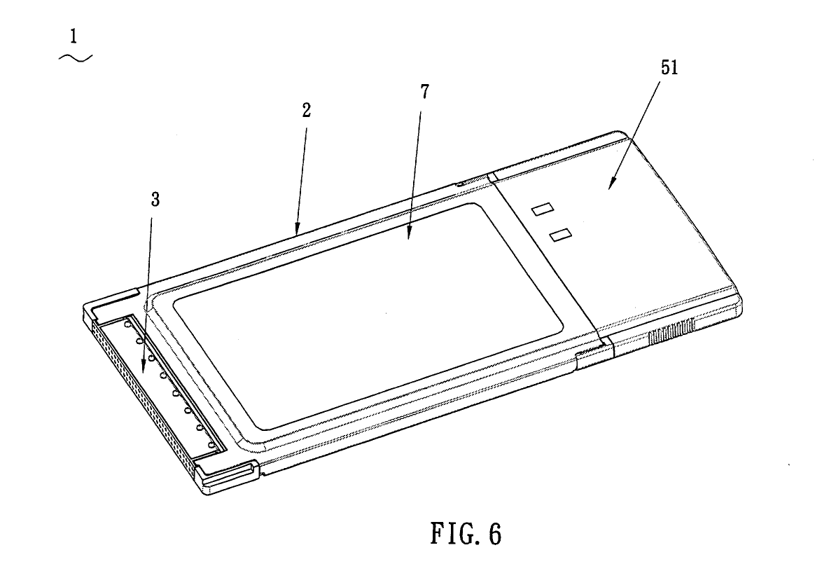

As shown in FIG. 13, the second shell 7 forms assembling arms 70 at opposite sides thereof. Each assembling arm 70 defines an assembling hole 701 for locking with the locking block 252, and forms an anchor 702 for interferentially cooperating with the biasing portion 25. The second shell 7 further has flanges 71 extending downwardly from opposite sides thereof. The flanges 71 form barbs 72 on edges thereof for abutting against the engaging edges 60 of the first shell 6. Each barb 72 has a width less than a width of each protruding plate 26 of the first bar 20 and the second bar 21. With reference to FIGS. 6 and 7, in assembly, the first shell 6 is mounted on the first bar 20 and the second bar 21. The engaging edges 60 are slantwise received in the latching slots 24 for enhancing resiliency. The first shell 6 forms convexes 61 in the vicinity of the engaging edges 60, and the barbs 72 press against convexes 61 of the first shell 6. The barbs 72 and the convexes 61 define space to accommodate repairing tools thereby facilitating repairing. The engaging edges 60 are removable from the latching slots 24 by repairing tools, whereby the first shell 6 is easily disassembled.

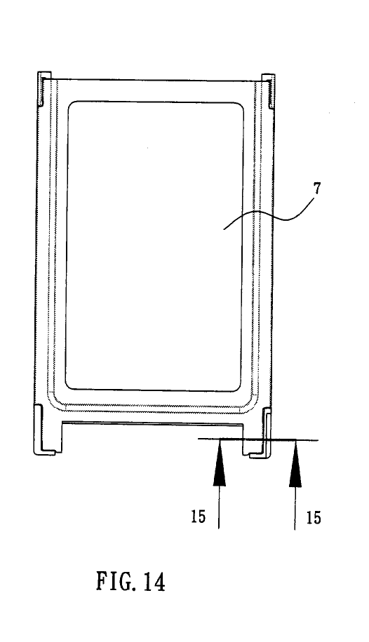

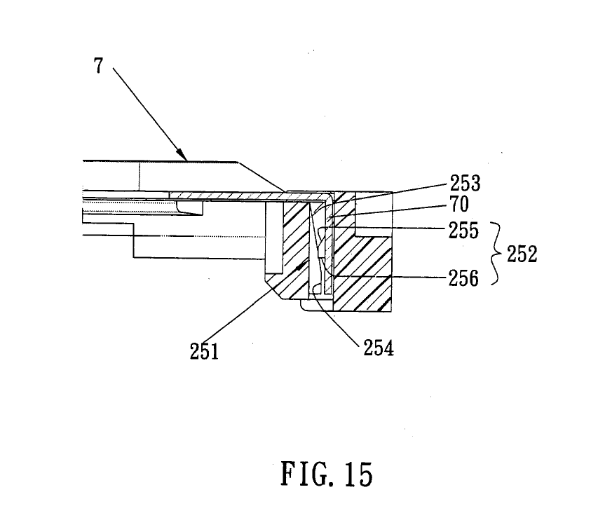

Referring to FIGS. 13-15, during assembly, the assembling arms 70 are got to move along the inclined surfaces 253 of the guiding blocks 251. Meanwhile the sloped surfaces 255 of the locking blocks 252 bias the assembling arms 70 to engage with the locking surfaces 256 and to abut against the biasing surfaces 254.

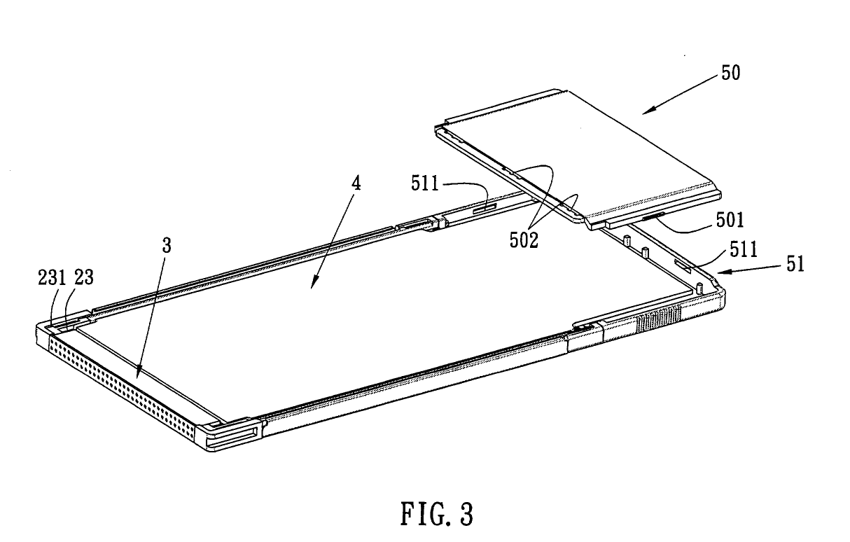

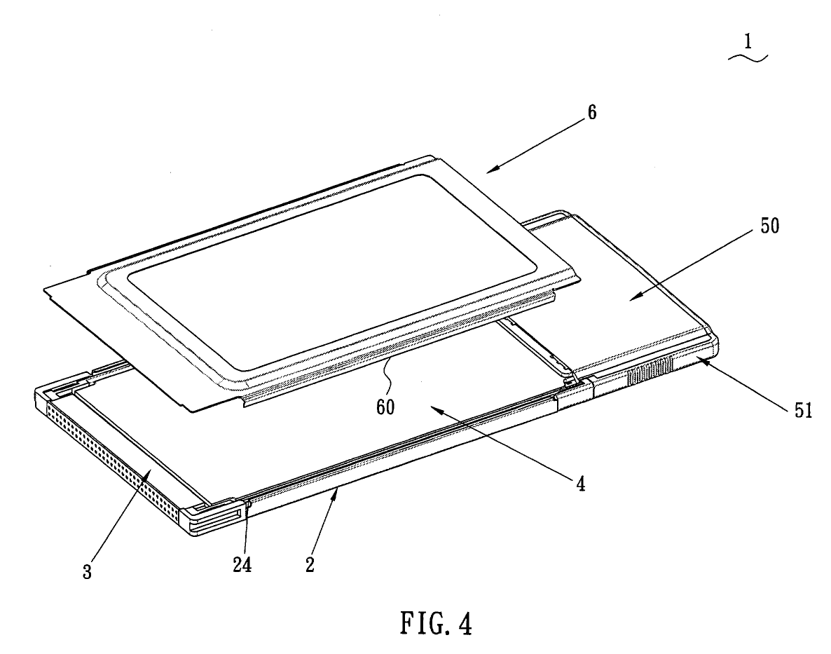

Referring to FIG. 3, the first cover 50 and the second cover 51 are assembled on an end of the first bar 20 and the second bar 21 and are opposite to the opening 23. The first cover 50 forms ribs 501 on opposite sides thereof, and the second cover 51 defines channels 511 for receiving the ribs 501. Further referring to FIGS. 1 and 4, the first cover 50 defines a plurality of locking holes 502, and the second cover 51 defines a plurality of locking holes 512. A plurality of protrusions 80 is formed on the first shell 6 and the second shell 7. As shown in FIG. 1, the protrusions 80 form locking portions 801 for interferentially cooperating with the locking holes 502, 512. The first cover 50 and the second cover 51 are separately formed, and therefore, the first cover 50 and the second cover 51 can be of different types and can be respectively assembled to the first shell 6 and the second shell 7.

It is understood that the invention may be embodied in other forms without departing from the spirit thereof. Thus, the present examples and embodiments are to be considered in all respects as illustrative and not restrictive, and the invention is not to be limited to the details given herein.

1. An electrical card comprising:
a dielectric housing including a first bar, a second bar and a transverse bar connecting ends of the first bar and the second bar, the first bar, the second bar and the transverse bar defining an opening for receiving a connector therein, tabs projecting inwardly from the first bar and the second bar for positioning the connector, the first bar and the second bar respectively forming protruding plates on bottoms thereof, latching slots being defined in the protruding plates, and biasing portions being respectively formed on ends of the first bar and the second bar;
a first cover and a second cover being engaged with each other and being assembled on ends of the first bar and the second bar and opposite to the opening, an engaging means for engaging the first cover and the second cover with the first bar and the second bar;
a fist shell for shielding the dielectric housing, forming engaging edges at opposite sides thereof for engaging with the latching slots of the first bar and the second bar;
a second shell for shielding the dielectric housing, having assembling arms for engaging with the biasing portion of the first bar and the second bar, and flanges extending downwardly from opposite sides thereof, barbs being formed on edges of the flanges for abutting against the engaging edges of the first shell; and
a printed circuit board (PCB) being received in the dielectric housing for electrically connecting with the connector for wireless transmission.

2. The electrical card as claimed in claim 1, wherein each biasing portion includes a guiding block and a locking block, the guiding block having an inclined surface inwardly inclined from an end of the biasing portion and a biasing surface extending from an end of the inclined surface, and the locking block having a sloped surface and a locking surface for guiding and locking the second shell.

3. The electrical card as claimed in claim 2, wherein the assembling arms have assembling holes for locking with the locking blocks of the dielectric housing.

4. The electrical card as claimed in claim 1, wherein and the first shell forms convexes in the vicinity of the engaging edges for abutting against the barbs of the second shell.

5. The electrical card as claimed in claim 4, wherein the barbs and the convexes define space to accommodate repairing tools thereby facilitating repairing.

6. The electrical card as claimed in claim 1, wherein each barb has a width less than a width of each protruding plate of the first bar and the second bar.

7. The electrical card as claimed in claim 1, wherein the engaging edges are slantwise received in the latching slots for enhancing resiliency.

8. The electrical card as claimed in claim 1, wherein the engaging means for engaging the first cover and the second cover with the first bar and the second bar, comprises a plurality of locking holes defined in the first cover and the second cover, and a plurality of protrusions formed on the first shell and the second shell for cooperating with the locking holes.

9. The electrical card as claimed in claim 8, wherein the protrusions form locking portions for interferentially cooperating with the locking holes.

10. The electrical card as claimed in claim 1, wherein the first cover forms ribs on opposite sides thereof, and wherein the second cover defines channels for receiving the ribs.

11. The electrical card as claimed in claim 1, wherein the assembling arms form anchors for interferentially cooperating with the biasing portion.

12. The electrical card as claimed in claim 1, wherein the protruding plates are spaced apart from the first bar and the second bar.
